(19) United States
(12) Patent Application Publication
(10) Pub. No.: US 2012/0125404 A1
(43) Pub. Date: May 24, 2012

(54) MODULAR SYSTEM FOR CONCENTRATION OF SOLAR RADIATION

(76) Inventor: Leonel José Dos Santos Teixeira Ramos, Gondomar (PT)

(21) Appl. No.: 13/388,024

(22) PCT Filed: Jul. 21, 2010
(86) PCT No.: PCT/PT2010/000034

§ 371 Date: Jan. 30, 2012

(30) Foreign Application Priority Data
Jul. 28, 2009 (PT) 104694

(51) Int. Cl. H01L 31/052; F24J 2/52

(52) U.S. Cl. 136/246; 126/606; 126/601

(57) ABSTRACT

Modular solar radiation concentrator system, which consists of using several flat reflectors mounted on a platform that transmits to each reflector rotation about two axes, allowing the concentration of solar radiation in an area or specific predetermined point in space. Each module is connected to a monitoring instrument, with specific software that allows knowing the sun's apparent path at the system installation site. Thus, the control of all reflectors of each module is conducted on their two axes of rotation so that solar radiation is, in every moment of the day, and every day of the year, focused or simply deviated to a particular point. The system described is specially devoted to solar concentration for the purpose of generating electricity, heat or both simultaneously, especially in buildings where the point of concentration may be, among others, a Stirling engine, a steam turbine or photovoltaic cells.

### BACKGROUND ART

Currently solar concentration is used in different ways, especially with the ultimate goal of obtaining electricity. More noticeably the use of solar concentration using parabolic disc, where the point of concentration is a Stirling engine or a photovoltaic system, and also concentration through lenses, prisms or parabolic reflectors, in this case usually only with photovoltaic cells.

Solar concentration allows most systems to achieve higher efficiencies with lower costs. In the case of Stirling engines, which run due to a temperature difference that is imposed between two points, its theoretical efficiency η is given by [1−T_{F}/T_{Q}], where T_{F} is the temperature of the cold side and T_{Q} is the temperature of the hot side (in Kelvin). Evidently, efficiency is greater the larger the difference between these two values. Solar concentration allows the hot side to reach high temperatures, thus moving away significantly from the temperature of the cold side, which is usually close to ambient temperature. In the case of photovoltaic technologies, increasing the incident energy per unit area usually allows an increase in power conversion efficiency and a reduction in the number of photovoltaic cells when compared to a system without concentration, which usually results in lower costs.

Quite often concentration is also used in thermal systems where high temperatures are required (e.g. for industrial processes), or for use in steam turbines to generate mechanical or electrical energy. The means of concentration in these cases are usually parabolic reflective surfaces.

The “U.S. Pat. No. 7,192,146—Solar concentrator array with grouped adjustable elements” mentions a device similar to the present invention, also with the function of concentration using different reflectors, but with important differences that present several limitations compared to the proposed system. Namely, the receiver system must be connected to the reflector module, because reflectors only have the ability to rotate over 1 axis with respect to said receiver. Such solution prevents the use of high power receivers, since the modules are not compatible with large dimensions. The scalability of the power of the receiver is not possible in this system within the module itself, since more reflectors cannot be simply added to increase that power. The system is not meant to accomplish the deviation of sunlight to a point or fixed area of space without concentration, as is proposed for the present invention for the deviation of sunlight, for example, to windows of buildings.

The application WO2005116534A2 discloses a solar energy generation controlling system that has an electronic control unit to drive motors to rotate concave mirrors, according to signals received by digital memory, clock and photo cells.

The application U.S. Pat. No. 3,905,352A discloses a system and apparatus for collecting, concentrating, transferring and storing for use solar radiant heat energy.

The application DE102005042478A1 discloses a tracking system for a solar energy collection unit that has controlled drives to adjust position by turning and tilting.

### SUMMARY OF THE INVENTION AND ADVANTAGES

The present invention is based on a modular array of heliostats, where only two motors can adjust the orientation of the reflectors in each module. The main application of the invention is the concentration or deviation of solar radiation for any type of stationary receiver for generating electricity, heat and/or light, where the location of the concentrator module(s) is independent from the receiver location. The main advantages of the invention are:
There is no solar receiver directly associated or even physically connected to the concentrator modules, allowing a total freedom in its choice and their location within a given area, with any inclination;
Any innovation or improvement of receiver systems (photovoltaic, Stirling engine, steam turbine, etc.) can be immediately used with the concentrator system;
Each module can be placed on the same plane as the surface where it rests without, although possible, lifting all or part of its structure, so it is easily hidden in building rooftops;
Each module can be relatively small (can have the size of a solar thermal panel, about 2 m²) which makes them easy to transport and assemble by a small number of installers;
Unlike the large parabolic concentrators discs, the wind forces on the surface of these modules are very small, so there is no need for special high-resistance support elements;
The fact that the concentration system is modular allows for a quick and easy increase or decrease of power of any receiver, by adding or removing concentrator modules;
The modular system does not have as sole functionality the concentration of sunlight to generate electricity or heat. It is possible to use it to redirect sunlight to areas where it is needed, such as windows, building facades without direct sunlight or where sunlight is otherwise required or preferred. The supports for the reflectors in each module can even be used without reflectors, and solar cells can be directly applied on them, without or with concentration, for example, with lenses. In this case, each support would be oriented at each moment perpendicular to the Sun's radiation for greater efficiency;
The modules can be applied on buildings facades with significant sun exposure in an aesthetically appealing manner, and may concentrate or just redirect solar radiation to one or more receivers located in the vicinity of these buildings.
Unlike the vast majority of concentration systems, the modular concentrator system, for being individually small and able to be installed along the support surface, safeguards the right to sunlight of surrounding areas. For example, the parabolic concentrators and panels with optical concentrators, both with solar trackers, need to be always perpendicular to solar radiation, and outside the vicinity of solar midday they cause significant shading on surrounding areas.
The fact that the receiver is motionless in the proposed invention makes it considerably easier, relatively to existing equipment, for the connection of said collector to the buildings hot water supply for solar heating or pre-heating.

### BRIEF DESCRIPTION OF DRAWINGS

The following description is based on the attached drawings which, without any limitations, represent:

FIG. 1—Schematic of the important points of the invention geometry.

FIG. 2—Reflector support of a module: Type-1 solution of the first mechanical scheme for the implementation of the invention.

FIG. 3—Reflector support of a module: Type-2 solution of the first mechanical scheme for the implementation of the invention.

FIG. 4—Reflector support of a module: mechanical solution of the second scheme for the implementation of the invention.

FIG. 5—Solution Type-2: details of the mechanism with connections to the reflector support, sequentially hinged in one direction (8, 13, 16).

FIG. 6—Solution Type-2: details of the single hinged mechanism with connection to the support of the reflector.

FIG. 7—General diagram of a concentrator module, comprising a plurality of reflector supports (18) and their motion transmission system (17).

FIG. 8—Detail of the rotational and translatory motion transmissions of reflectors for the type-1 solution.

FIG. 9—Detail of the translatory motion transmission to reflectors for the type-2 solution.

FIG. 10—General outline of the method for solar concentration.

### DETAILED DESCRIPTION OF THE INVENTION

The present invention consists on a modular solar concentration system that can be used for both concentration (main application) or simply for the deviation of solar radiation. The system comprises at least one array of reflective heliostats (18) where each of the heliostats tracks the sun's apparent motion and directs its radiation to an area or point receiver (30). This is possible using just (or at least) two motors, where these make possible adjusting the orientation of each of the reflectors of the array. The location of the reflector module(s) (29) is independent of the location of the receiver (30), which has the advantages mentioned above. Tracking the sun's apparent motion is achieved through a control system that operates on the motors of each module by means of a computer (31) to direct the reflected solar radiation to the receiver location.

In order to be able to deviate solar radiation to a specific point or area by means of a modular concentration system so that it performs as an heliostat, it is necessary that each reflector within each module can track the apparent motion of the sun (elevation and azimuth) without its midpoint suffering significant deviations in terms of relative coordinates (X, Y, Z) to the point of concentration. This is because significant deviations of these coordinates would prevent changes in the angles of each reflector from being equal for all reflectors within the same module, which would make necessary for each reflector to have independent control motors. Thus, the fact that the receiver is stationary for the purpose of concentration allows for each reflector, by being adjusted individually on its support and for a radiation with the same characteristics in terms of incidence angles in each individual reflector, for the reflections of all the reflectors of all modules to intersect at a single point or area of space, consequently achieving solar radiation concentration. To this end, each reflector is fixed on its support plane by any adjustable system, such as a three point support, where the distance of each point to the support plane is adjustable.

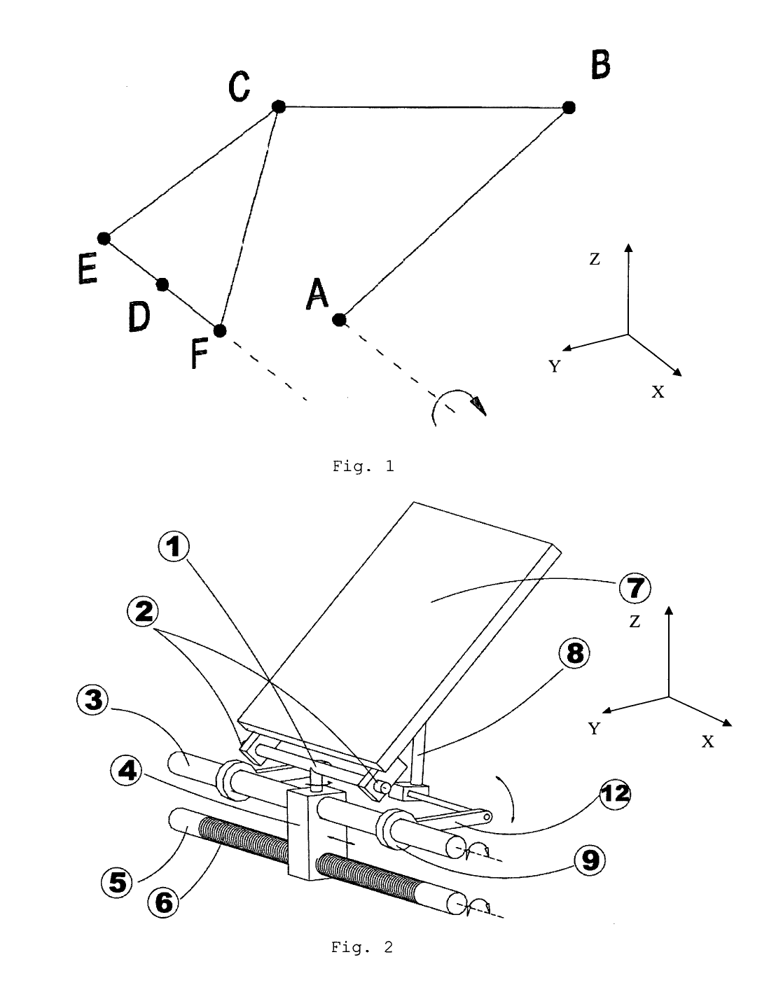

The problem was solved using two possible mechanical schemes that can be interpreted with the aid of FIG. 1 and are embodied in FIGS. 2 to 9. In the first mechanical scheme, points (ABC) define a fixed plane, where point (A) is motionless and represents the centre of rotation of bar (AB), (12) around an axis perpendicular to said plane (parallel to X axis) hinged at (B) in an axis parallel to X. Any rotation of bar (AB) around (A) in the axis perpendicular to the plane (ABC) moves the bar (AB), which also moves the bar (CB), (8), hinged at (C), (16) in all directions (XYZ). The plane defined by points (CEF) is the support plane for reflectors (7). Point (D), (1) is collinear with (EF), and has an outside link, hinged in an axis parallel to Z. Point (D) can be displaced only over the X direction. Then, when the XY coordinates of point (C) are different from the point (D), any movement of point (D) in a direction parallel to X causes a rotation about an axis parallel to Z of the plane of the reflector support (CEF) with centre at (C), causing a rotation about the axis parallel to Z of segment (EF), where only point (D) maintains its Y coordinate constant. In addition, any rotation of point (A) around the axis parallel to X causes a rotation of the plane of the reflector on the axis of segment (EF). The combination of displacements at (D) with rotations over (A) allows the normal of the reflector support plane (CED) to be oriented in a multitude of directions. Theoretically, all directions of space can be achieved for certain lengths (AB), (BC), (EF) and spatial position of (A) relatively to (D). However, physically, the segments have fixed dimensions and cannot intersect since they are made of solid objects, but since the directions of interest are between −X to +Y to +X and +Y to +Z, this dows not pose as an obstacle to the validity of this solution for the applications in consideration.

In the second mechanical scheme, point (A) is invariant in space and represents the centre of rotation of bar (AB) (12) around an axis parallel to X. Any rotation of (A) around the axis parallel to X moves bar (AB), which moves bar (BC), (8), hinged at (B) and (C), 16, in all directions (XYZ). Point (C) does not belong to the plane perpendicular to (EF) that contains point (D) (FIG. 4). The plane defined by points (CEF) is the support plane of reflectors (7). Point (D) is collinear with (EF), and has a link to the outside, hinged in an axis perpendicular to (EF) and belonging to plane (CEF). Plane (CEF) can rotate about an axis parallel to X because of the link to the outside of point (D), (1). This provides the reflector support a lifting motion in a first direction. Given that point (C) does not belong to the plane perpendicular to (EF) that passes through (D), any movement of the point (C), since it is eccentric to the axis defined by the intersection of that plane with the plane of the reflector support (CEF), makes the reflector support rotate in a second direction. The combinations of rotations in both directions allow the normal to (CED) of the reflector support to be oriented in a multitude of directions. The rotation is limited in both directions by the dimensions of the various components and the contact between elements within the limits of rotation. However, this solution covers a range of movements of the reflector supports which is high enough to make modular systems of concentration or deviation of solar radiation possible.

FIG. 2 represents a possible implementation of the first mechanical scheme (solution type-1) of a reflector support system. Bar (5), threaded (6), when it rotates on its axis, requires that piece (4), which contains internal thread in contact with bar (5), to move in the direction of that bar (as point (D) of FIG. 1). For this, it uses bar (3), parallel to (5), which slides in the connection with piece (4) that prevents piece (4) itself from rotating. It should be noted that the impediment for piece (4) to rotate can be achieved with the aid of any other bar parallel to (5) besides (3). The “T-shaped” bar (1) is hinged around the Z axis in the connection to (4), while still allowing rotation of the reflector support (7) about itself in the contact points. The fixed bar (3), when rotating on its axis, passes by means of rod (9) (equivalent to bar (AB) in FIG. 1) movement to bar (8) (equivalent to the bar (BC) in FIG. 1) to the point represented by (C) in FIG. 1, located behind the support of the reflector. The thread (6) of bar (5) should be protected with a flexible sleeve against dirt and corrosion.

In summary, FIG. 2 represents part of the proposed modular concentrator system of solar radiation, which can be achieved using an array of sun-tracking heliostats comprising a plurality of elements in row (3) and (5), which are positioned at least partially between at least two opposing supports. A first plurality of the elements in a row (3) can rotate in a first axis and a second plurality (5) can rotate in a second axis parallel to the first, the latter with external thread (6) at least partially on its length. The various elements for the reflector support (7) are mounted simultaneously over at least two elements in a row with possibility to rotate in said first and second axis through a first connection mechanically coupled to the first plurality of elements in row (3), such that the motion of link (9) results in the rotation of element (12) over the axis of said row element, and consequently in the movement of a connecting element (8) to the reflector support (7). A second connection is also used from (1) to (4) hinged in the Z axis, and hinged in (2) in the axis of the connecting rod to the reflector support (7), to materialize the mechanically coupled connection to the second plurality of elements in a row. The rotation of this element in a row results in the translatory motion of the connecting element (4) in the direction of the axis of said element in a row. Using at least two motors (19, 21), configured to move each of the links attached to each of the two pluralities of elements in a row, it is possible to perform solar tracking.

Although obvious, it is important to note that the solar radiation modular concentrator as described above can be characterized by having at least one link mechanically coupled to the second plurality of elements of row that has internal thread (4) and is in contact with the outer thread (6) of said second plurality of elements in row (5) and be prevented from rotating by an element with an axis parallel to the second plurality of elements, which means it can be any other, including the first plurality of elements row (3), which is what is represented in FIG. 2.

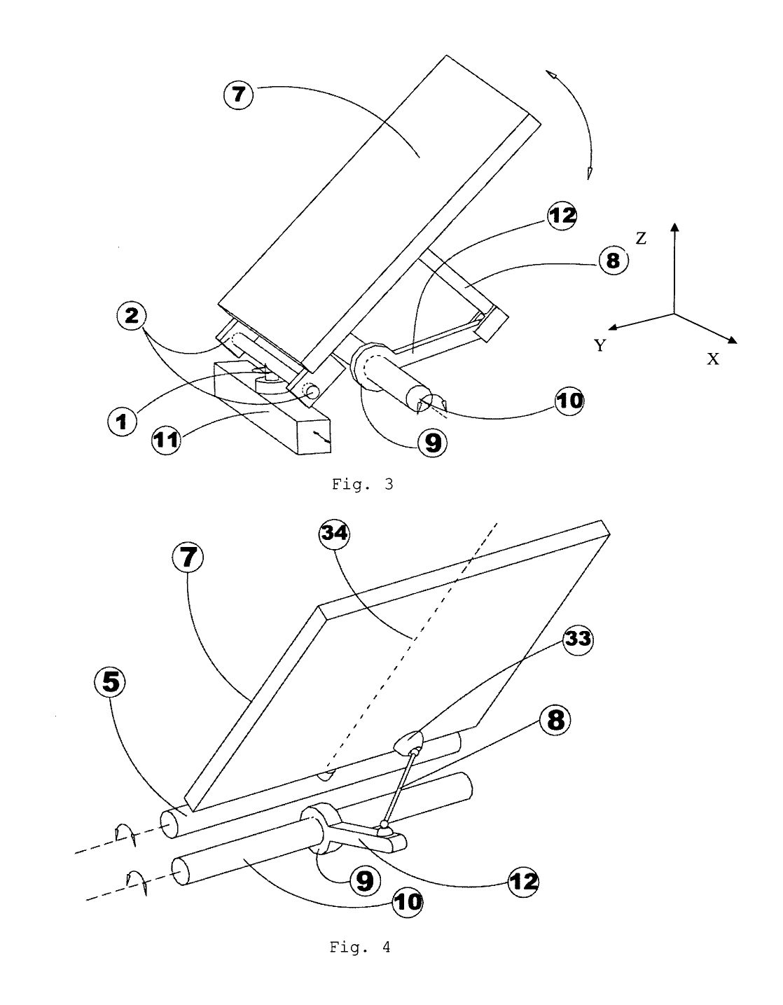

FIG. 3 shows another possible implementation of the first mechanical scheme (solution type-2) of the system consisting of conveying motion to the “T-shaped” bar (1) directly through a translatory bar (11), instead of a rotating bar. In this case the rotating bar (10) assumes any position parallel to (11).

In FIG. 4 it is shown a possible implementation of the second scheme described for FIG. 1, which consists of transmitting only rotation to bars (5) and (10), with rod (8) in contact with the reflector support (7) at a point other than the axis of rotation of said reflector support over its connection to bar (5). Thus, the rotation of bar (5) gives the reflector support a lifting motion and the rotation of bar (10), by means of at least one bar (8), gives the reflector support rotation on an axis perpendicular to the first, where this combination results in a myriad of solutions for its orientation.

In more detail, FIG. 4 represents part of the modular system proposed for solar radiation concentration, which can be characterized by an array of heliostats comprising a plurality of elements in row (5) and (10), which are positioned least partially between at least two opposing supports. A first plurality of elements in row (5) are rotational over a first axis and a second plurality (10) are rotational over a second axis parallel to the first. A plurality of reflectors support elements are mounted simultaneously on at least two elements in row with the first and second rotation axis through a first connection mechanically coupled to the first plurality of elements in a row, such that the movement of the link (9) results in rotation of the element (12) over the axis of the row element (10) and in rotation, via element (8) with link (33) eccentric to axis (34), of the reflector support plane (7) around that axis (34). In addition, there is a second connection mechanically coupled to the second plurality of elements in row (5), such that the rotation of the element in row results in rotation of the reflectors support plane (7) around the axis of that element (5). Using at least two motors configured to move each of the links attached to each of the two pluralities of elements in a row, one can perform solar tracking.

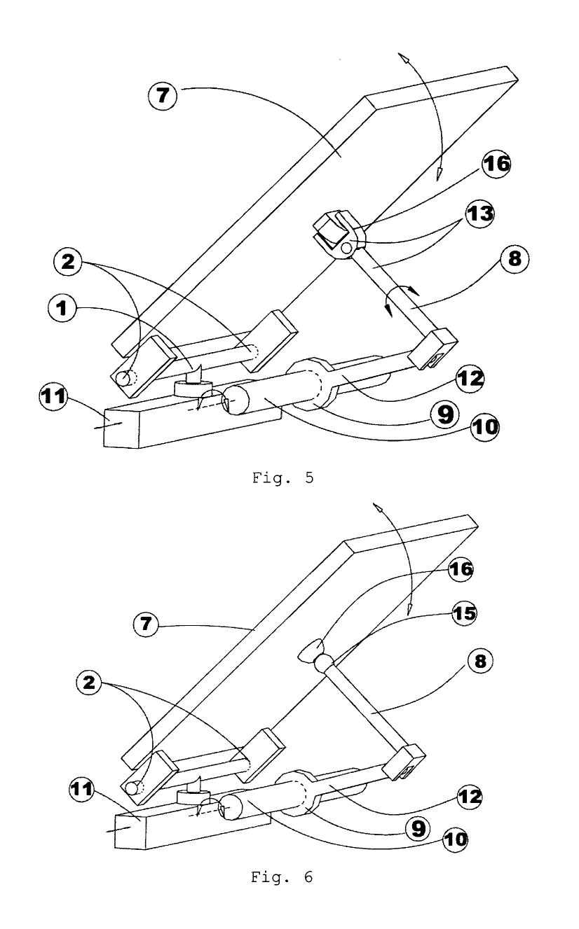

In FIG. 5 and FIG. 6 details of implementation of the (XYZ) hinge behind the reflector support are presented, where this can be achieved with unidirectional hinges successively linked (13) or a spherical bearing (15), respectively.

FIG. 7 presents a general outline of a concentrator module, which consists of a frame with several reflectors (18), displaying also zone (17) with the transmission shafts that allow the simultaneous movement of all the reflector supports. The heliostats may include fixings between the opposing supports, provided by a chassis, and this chassis may have fixings to the exterior. In FIG. 7 we can see that a feasible and optimized provision of each module consists on the ordering of heliostats on a rectangular array, with multiple rows and columns.

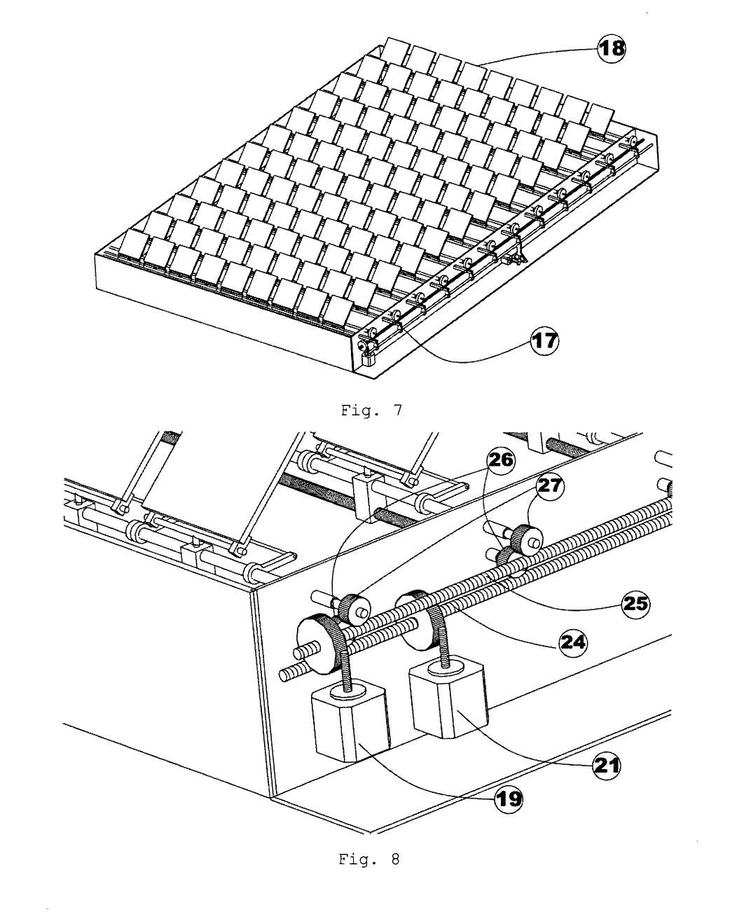

In more detail, in FIG. 8, two motors are detailed, (19) and (21), which control two independent shafts (24) and (25), each passing rotation through mechanisms in (26) and (27) to two bars (3) and (5) which comprise the type-1 solution.

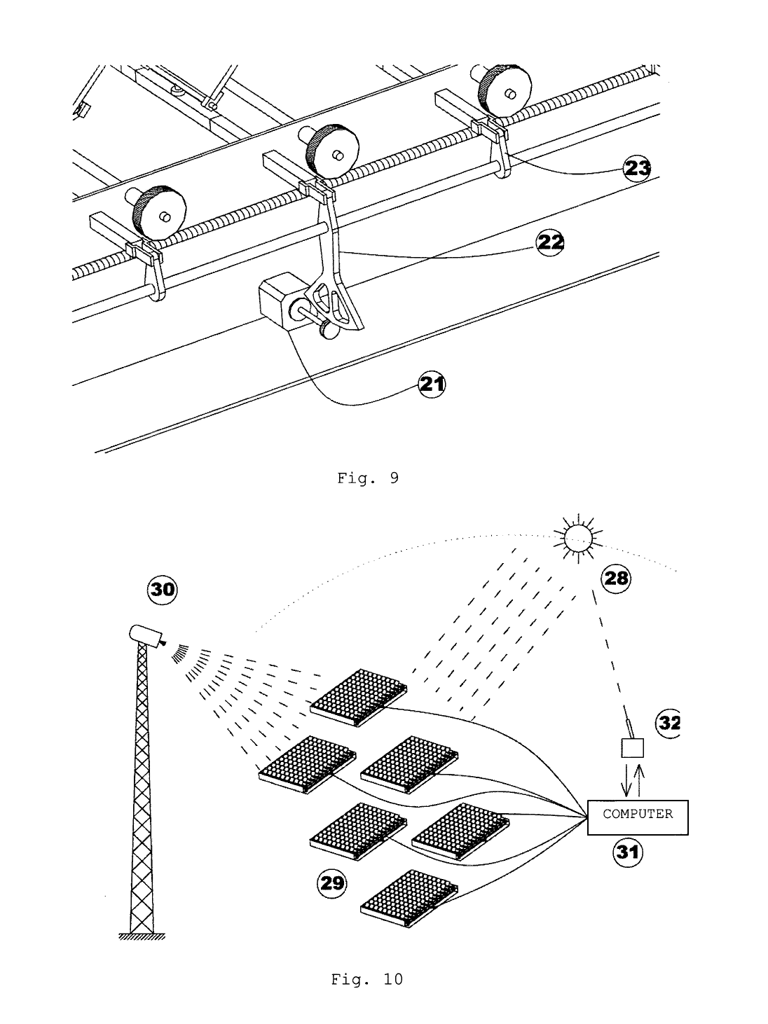

FIG. 9 presents a way to carry translatory motion to bars (11) of the type-2 solution, via a lever system, in which the motor (21) causes the rotation of a part (22) on the axis of longitudinal support bar, where through parts (23) the translatory motion is passed on to bars (11) (FIG. 3). The rotation of the bars is therefore possible through the mechanically coupled links, which lie for example alongside one of the supports, which provide interconnection with the motors.

FIG. 10 shows the operation of the modular system for solar concentration, where several concentrator modules (29) reflect the incident radiation from the Sun during its apparent motion (28) to a given stationary receiver (30). Tracking the sun's apparent motion is achieved through a control system that operates on the motors of each module by a computer (31) that may simply internally possess all the information of annual apparent position of the Sun in the sky, or in addition have also a monitoring system of solar positioning (32) that may allow making adjustments to the computer's internal clock, so that solar tracking is more accurate. The receiver may consist on any of several existing systems, such as a Stirling engine, solar cells, steam turbine or a heat exchanger. The system can also be used to perform only the deviation of solar radiation, without concentration, for windows of buildings or solar tubes (which consist of tubes with mirrored inner surfaces to guide light into desired locations inside buildings), in order to illuminate and/or heat spaces that otherwise would not receive direct sunlight, such as the facades facing North (in the northern hemisphere) or underground basements.

As mentioned, the motors of each module are directly connected to a central control that transmits to them information concerning the position they should take so that solar radiation is reflected to a known point. It may be useful, however, that each concentrator module contains a memory accessible by computer with stored information concerning the position of reflectors. Thus, the central control system does not need to store the information of the N modules that can be present in a given concentration system.

In FIG. 7 area (17) shall be protected by a cover in order to prevent motors from being damaged by environmental factors, as well as to ensure that the existing mechanical linkages, possibly lubricated, are protected from corrosive agents and dirt.

1. A Modular solar radiation concentrator system (29) for concentration or deviation of solar radiation, comprising
at least one array of reflective heliostats (18) where each follows the Sun's apparent motion directing its radiation to a receiver area or point (30) in which with only two motors it is able to adjust the orientation of each of the reflectors of the array, where those motors trigger support mechanisms (7) of said reflectors;
the reflector module location (29) being independent of the location of the receiver (30);
a control system (31) that operates the motors of each module in order to follow the Sun's apparent movement and direct reflected solar radiation to the said specific location,
wherein the mechanism for supporting reflectors comprises:
a point (A) of invariable position in space which characterizes the center of rotation of at least one bar (AB, 12) around an axis perpendicular to plane (ABC), where said bar(s) is (are) hinged in (B) in an axis parallel to X;
a connecting rod (BC, 8) to a reflector support plane (CEF, 7) hinged at the contact point (C, 16) or at any part of bar (BC, 8) in all directions of space (XYZ), point (D, 1) being collinear with segment (EF), said point (D, 1) having a hinged connection in an axis parallel to Z to the outside, and said point (D, 1) being translatory at least along the X direction.

2. The Modular system for concentration of solar radiation, according to claim 1, wherein the mechanism for supporting reflectors comprises:
a point (A) of invariable position in space characterizing the center of rotation of at least one bar (AB, 12) about an axis perpendicular to the plane perpendicular to X which contains point (A), where said bar(s) are hinged in (B) in all directions of space (XYZ);
a connecting rod (BC, 8) to a reflector support plane (CEF, 7) hinged at the point of contact (C, 33) in all directions of space (XYZ), or in any part of bar (BC, 8), where point (C, 33) does not belong to the plane perpendicular to X containing point (D, 1), and point (D, 1) is collinear with segment (EF), and point (D, 1) has a connection to the outside hinged on an axis (34) perpendicular to (EF) and belonging to the plane (CEF, 7), and point (D, 1) is rotational on an axis parallel to X.

3. The Modular system for concentration of solar radiation according to claim 1, further comprising an array of heliostats comprising:
a plurality of elements in row, positioned at least partially between at least two opposing supports, where a first plurality of elements in row (5) are rotational about one axis and a second plurality (11) are translatory about a direction;
a plurality of reflector support elements (7) mounted simultaneously on at least two elements in a row, one with rotational and the other translatory characteristics;
a first link mechanically coupled to the first plurality of elements in row, such that the link motion (9) results in rotation of the element (12) on the axis of the element in row (11), and hence in the movement of an element (8) of connection to the reflector support (7);
a second link (1) hinged at Z, and at (2) in the axis of said connecting link to the reflector support (7), and mechanically coupled to the second plurality of elements in row such that the translatory motion of the element in row (11) results in the translatory motion of the link (1) in the direction of its axis; and
at least two motors (19, 21) configured to move each of the links attached to each one of the two pluralities of elements in row.

4. The Modular system for concentration of solar radiation according to claim 1, further comprising an array of heliostats comprising:
a plurality of elements in row, positioned at least partially between at least two opposing supports, where a first plurality of row elements (3) are rotational about a first axis and a second plurality (5) are rotational about a second axis parallel to the first, with external thread (6) at least partially in its length;
a plurality of reflector support elements (7) mounted simultaneously on at least two elements in row with said first and second rotation axis;
a first connection mechanically coupled to the first plurality of elements in row (3), such that the motion of link (9) results in rotation of the element (12) over the axis of the row element, and hence the movement of an element (8) for connection to the reflector support (7);
a second connection from (1) to (4) hinged about Z, and hinged at (2) over the axis of the connecting link to the reflector support (7), and mechanically coupled to the second plurality of elements in row, such that the rotation of the element in row results in the translatory motion of the connecting element (4) in the direction of the axis of said row element; and
at least two motors (19, 21) configured to move each of the links attached to each of the two pluralities of elements in rows.

5. The Modular system for concentration of solar radiation according to claim 1, further comprising an array of heliostats comprising:
a plurality of elements in row, positioned at least partially between at least two opposing supports, where a first plurality of row elements (5) are rotational about a first axis and a second plurality (10) are rotational about a second axis parallel to the first;
a plurality of reflector support elements mounted simultaneously on at least two elements in row with said first and second rotation axis;
a first connection mechanically coupled to the first plurality of elements in row, such that the movement of the link (9) results in rotational motion of element (12) about the axis of the element of row (10) and in rotation motion, through element (8) with link (33) eccentric to axis (34), of the reflector support plane (7) around axis (34);
a second connection mechanically coupled to the second plurality of elements in row (5), such that the rotation of the element in row results in rotation of the reflector support plane (7) around the axis of that element (5); and
at least two motors to move each set of links coupled to each of the two pluralities of elements in row.

6. The Modular system for concentration of solar radiation according to claim 5, further comprising at least one connection mechanically coupled to the second plurality of row elements having internal thread (4), in contact with the outer thread (6) of said second plurality of row elements (5) and being prevented from rotating by an element with its axis parallel to that of the second plurality of row elements.

7. The Modular system for concentration of solar radiation according to claim 5, characterized by the element that prevents link (4) from rotating, mechanically coupled to the second plurality of elements in row (5), is the first plurality of row elements (3).

8. The Modular system for concentration of solar radiation according to claim 7, further comprising a flexible sleeve for protection of the external thread (6), of the second plurality of elements in row, against dirt and corrosion.

9. The Modular system for concentration of solar radiation according to claim 4, further comprising links mechanically coupled to the plurality of elements in row is positioned next to any of the opposing supporters.

10. The Modular system for concentration of solar radiation according to claim 4, further comprising protective covers on all links and motors.

11. The Modular system for concentration of solar radiation according to claim 1, further comprising a computer-accessible memory that stores the orientation of the plurality of reflective elements.

12. The Modular system for concentration of solar radiation according to claim 4, where the assembly of each reflector on its support plane is accomplished by fasteners that allow adjustable spacing between each reflector and its support plane.

13. The Modular system for concentration of solar radiation according to claim 1, wherein the receiver consisting of a Stirling engine, photovoltaic cells, a steam turbine or a heat exchanger, where the heat exchanger can be combined simultaneously with any of the others, or a window, a skylight or solar tube to distribute light throughout the interior of buildings.

14. The Modular system for concentration of solar radiation according to claim 5, further comprising links mechanically coupled to the plurality of elements in row is positioned next to any of the opposing supporters.

15. The Modular system for concentration of solar radiation according to claim 5, further comprising protective covers on all links and motors.

16. The Modular system for concentration of solar radiation according to claim 5, where the assembly of each reflector on its support plane is accomplished by fasteners that allow adjustable spacing between each reflector and its support plane.
